(19) United States
(12) Patent Application Publication
(10) Pub. No.: US 2019/0371635 A1
(43) Pub. Date: Dec. 5, 2019

(54) PLASMA PROCESSING APPARATUS AND SEMICONDUCTOR DEVICE MANUFACTURING METHOD

(71) Applicant: TOSHIBA MEMORY CORPORATION, Minato-ku (JP)

(72) Inventor: Tomoya OORI, Kuwana (JP)

(73) Assignee: TOSHIBA MEMORY CORPORATION, Minato-ku (JP)

(21) Appl. No.: 16/271,921

(22) Filed: Feb. 11, 2019

(30) Foreign Application Priority Data
May 31, 2018 (JP) 2018-104619

(51) Int. Cl. H01L 21/67; H01L 21/677; H01L 21/687; H01L 21/3065; H01J 37/32

(52) U.S. Cl. CPC H01L 21/67259; H01L 21/67069; H01L 21/67742; H01L 21/68707; H01L 21/3065; H01L 21/6831; H01J 37/32715; H01J 2237/3341; H01J 2237/20221; H01J 2237/24578; H01J 37/32642

(57) ABSTRACT

According to one embodiment, the plasma processing apparatus includes a support table configured to support a substrate, an edge ring provided at an outer periphery of the support table on a side with a mounting surface for placing the substrate thereon, a transfer arm configured to transfer the substrate onto the support table, a sensor configured to detect a position of the edge ring, a drive part configured to drive the transfer arm, and a controller configured to control the drive part. The controller is configured to calculate an offset amount between a center position of the edge ring and a center position of the substrate under transfer by the transfer arm, on a basis of information output from the sensor, and correct a movement amount of the transfer arm by using the offset amount.

### CROSS-REFERENCE TO RELATED APPLICATIONS

This application is based upon and claims the benefit of priority front Japanese Patent Application No. 2018-104619, filed on May 31, 2018; the entire contents of which are incorporated herein by reference.

### FIELD

Embodiments described herein relate generally to a plasma processing apparatus and a semiconductor device manufacturing method.

### BACKGROUND

In a plasma processing apparatus, a wafer is supported by a support member. The support member includes a support table having an outer contour of a circular shape, and an edge ring disposed along the outer periphery of the upper surface of the support table. If the center of the support table and the center of the edge ring do not agree with each other, the processing rate at the outermost periphery of the wafer becomes asymmetric, and the plasma process ends up being uneven.

### BRIEF DESCRIPTION OF THE DRAWINGS

FIG. 1 is a sectional view schematically illustrating a configuration example of a plasma processing apparatus according to a first embodiment;

FIGS. 2A and 2B are diagrams illustrating an example of a transfer arm according to the first embodiment;

FIG. 3 is a diagram illustrating an example of a transfer method for an object substrate in an ideal state;

FIGS. 4A to 4D are diagrams illustrating an example of detection of the position of an edge ring according to the first embodiment;

FIG. 5 is a diagram illustrating an outline of a placement position correcting method for an object substrate according to the first embodiment;

FIG. 6 is a flowchart illustrating an example of the sequence of a plasma processing method according to the first embodiment;

FIG. 7 is a diagram illustrating a hardware configuration example of a controller; and

FIGS. 8A and 8B are diagrams schematically illustrating a configuration example of a plasma processing apparatus according to a second embodiment.

### DETAILED DESCRIPTION

According to one embodiment, the plasma processing apparatus includes a support table configured to support a substrate in a chamber, an edge ring provided at an outer periphery of the support table on a side with a mounting surface for placing the substrate thereon, a transfer arm configured to transfer the substrate onto the support table, a sensor configured to detect a position of the edge ring, a drive part configured to drive the transfer arm, and a controller configured to control the drive part. The controller is configured to calculate an offset amount between a center position of the edge ring and a center position of the substrate under transfer by the transfer arm, on a basis of information output from the sensor, and correct a movement amount of the transfer arm by using the offset amount.

Exemplary embodiments of a plasma processing apparatus and a semiconductor device manufacturing method will be explained below in detail with reference to the accompanying drawings. The present invention is not limited to the following embodiments.

### First Embodiment

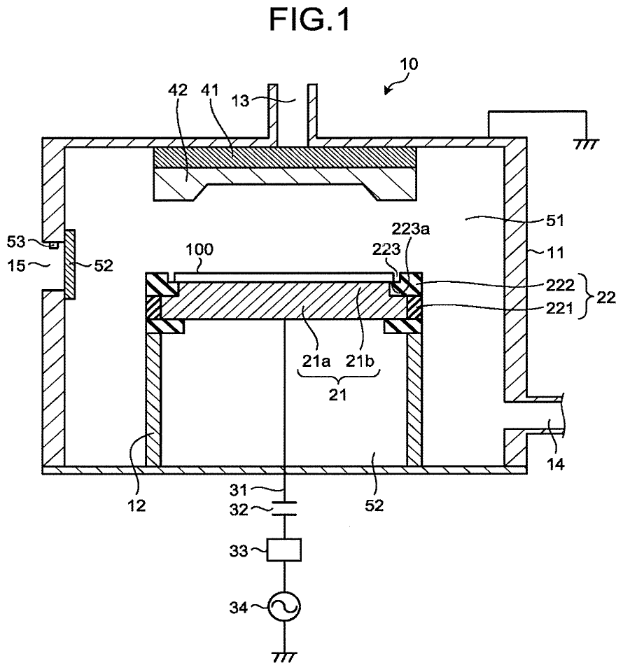

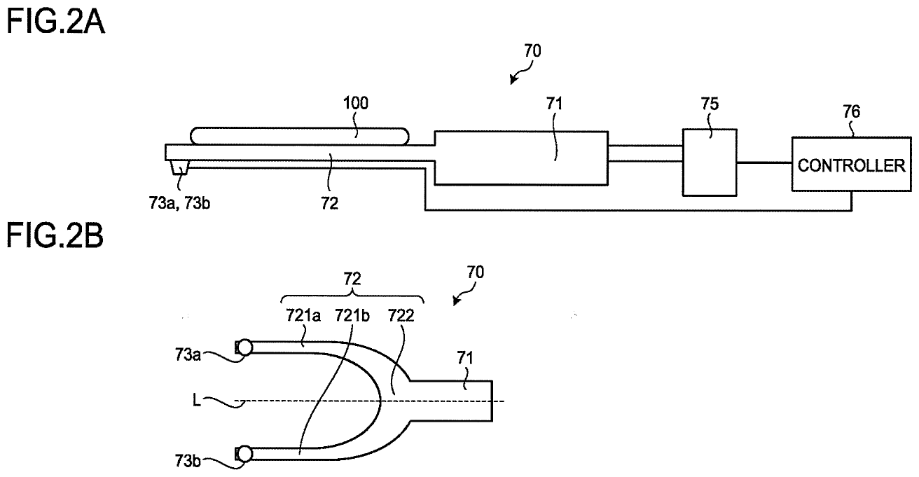

FIG. 1 is a sectional view schematically illustrating a configuration example of a plasma processing apparatus according to a first embodiment. FIGS. 2A and 2E are diagrams illustrating an example of a transfer arm according to the first embodiment. Here, FIG. 2A is a side view, and FIG. 25 is a bottom view. Here, the plasma processing apparatus 10 is exemplified by a Reactive Ion Etching (RIE) apparatus. The plasma processing apparatus 10 includes a chamber 11 made of, e.g., aluminum and structured airtight. This chamber 11 is grounded.

The chamber 11 is provided with a support table 21 inside, which is configured to support an object substrate 100 to be treated as a processing object in a horizontal state, and to function as a lower electrode. The support table 21 is equipped with a holding mechanism (not illustrated) on its surface, such as an electrostatic chuck mechanism for attracting and holding the object substrate 100 by an electrostatic force. The support table 21 has a shape formed of two circular columns, which are different in diameter and stacked up and down. Specifically, the support table 21 has a structure integrally formed of a larger-diameter portion 21a having a first diameter and a smaller-diameter portion 21b having a second diameter smaller than the first diameter. The smaller-diameter portion 21b is arranged on the upper side, and the upper surface of the smaller-diameter portion 21b serves as a mounting surface for the object substrate 100. Here, the mounting surface for the object substrate 100 has a circular shape smaller than the area of the object substrate 100 to be placed on the support table 21. On the other hand, the upper surface of the larger-diameter portion 21a serves as a mounting surface for an upper edge ring 222.

An edge ring 22 is provided along the side surface of the support table 21. The edge ring 22 is a member provided to adjust an electric field, during etching to the object substrate 100, such that the electric field is not deflected in the vertical direction (the direction perpendicular to the object substrate plane) at the peripheral portion of the object substrate 100. The edge ring 22 includes a lower edge ring 221 arranged along the side surface of the larger-diameter portion 21a of the support table, and the upper edge ring 222 arranged along the side surface of the smaller-diameter portion 21b. The position of the upper surface of the lower edge ring 221 is almost flush with the position of the upper surface of the larger-diameter portion 21a, i.e., the edge ring mounting surface of the support table 21. The lower edge ring 221 is secured on the side surface of the larger-diameter portion 21a. The upper edge ring 222 is detachably mounted on the edge ring mounting surface of the support table 21 and on the upper surface of the lower edge ring 221. The upper edge ring 222 has a stepwise structure 223 in which the upper surface on the inner peripheral side is lower than the upper surface on the outer peripheral side. The stepwise structure 223 provides a terrace 223a that serves as a mounting surface for the object substrate 100. The position of the terrace 223a of the stepwise structure 223 is almost flush with the position of the upper surface of the support table 21. The support table 21 has a circular column shape, and thus each of the lower edge ring 221 and the upper edge ring 222 has a circular ring shape.

Further, the support table 21 is secured by a support frame 12 in a state positioned at about the center inside the chamber 11. The support table 21 is connected to a feeder line 31 for supplying a radio frequency power, and this feeder line 31 is connected to a blocking capacitor 32, a matching device 33, and a radio frequency power supply 34. The radio frequency power supply 34 is configured to supply a radio frequency power having a predetermined frequency to the support table 21.

An upper electrode 42 is provided above the support table 21, and faces the support table 21 functioning as the lower electrode. The upper electrode 42 is secured by a member 41, which is provided near the upper side of the chamber 11 and separated from the support table 21 by a predetermined distance, such that the upper electrode 42 and the support table 21 face each other in parallel. With this structure, the upper electrode 42 and the support table 21 constitute a pair of parallel-plate electrodes. Further, the upper electrode 42 includes a plurality of gas supply passages (not illustrated) formed therein and penetrating the upper electrode 42 in the thickness direction. The upper electrode 42 has a circular plate shape, for example. The upper electrode 42 is an electrode made of silicon, for example.

The chamber 11 is provided with a gas supply port 13 above the arrangement position of the upper electrode 42, to supply a processing gas for use in a plasma process. The gas supply port 13 is connected to a gas supply unit (not illustrated) through a pipe.

The chamber 11 is provided with a gas exhaust port 14 on the lower side. The gas exhaust port 14 is connected to a vacuum pump (not illustrated) through a pipe.

The chamber 11 is provided with an opening 15 on a side surface, through which, for example, the object substrate 100 is loaded or unloaded, and the opening 15 is provided with a shutter 52. The shutter 52 serves to separate the outside and inside of the chamber 11 from each other, and can be opened to connect the opening 15 to the inside of the chamber 11 when the object substrate 100 is to be loaded or unloaded. The opening 15 is equipped with a sensor 53, which detects the position of the object substrate 100 relative to a transfer arm 70, as the transfer arm 70 transfers the object substrate 100 into the chamber 11. The sensor 53 is formed of a distance sensor, for example. The sensor 53 is connected to a controller 76 described later through a signal line.

The object substrate 100 is transferred by the transfer arm 70. As illustrated in FIGS. 2A and 2B, the transfer arm 70 includes an arm 71 and a U-shaped pick 72 provided at one end of the arm 71. The pick 72 includes two substrate holding members 721a and 721b extending in the transfer direction, and a connecting member 722 that connects one-side ends of the substrate holding members 721a and 721b to each other.

The two substrate holding members 721a and 721b are respectively equipped with sensors 73a and 73b at the lower face distal ends. Each of the sensors 73a and 73b is formed of a height sensor (distance sensor) for detecting the position (height) of a substance present below the sensor 73a or 73b. As described above, the position of the upper surface on the outer peripheral side of the upper edge ring 222 is higher that the position of the substrate mounting surface of the support table 21. Accordingly, the position of the upper edge ring 222 can be specified from data about height obtained by the sensors 73a and 73b during movement of the transfer arm 70. Here, the arrangement positions of the sensors 73a and 73b are in a line symmetric relation with respect to a hypothetical line L formed by extending the arm 71 toward the pick 72. In order to achieve this relation, the arm 71 preferably has a shape that is line symmetric with respect to the hypothetical line L.

The transfer arm 70 is connected to a drive part 75 and a controller 76. The drive part 75 is connected to one end of the arm 71, and is configured to drive the transfer arm 70 in accordance with an instruction from the controller 76 to transfer the object substrate 100 to a predetermined position. Here, it is assumed that the transfer arm 70 passes through a predetermined position in the opening 15 of the chamber 11.

The controller 76 is configured to control the drive part 75 to transfer the object substrate 100 onto the support table 21. At this time, until the object substrate 100 reaches a position above the support table 21, the controller 76 sends an instruction to the drive part 75 to transfer the object substrate 100, so as to cause the center of the object substrate 100 under transfer to agree with the center of the support table 21. Then, after the object substrate 100 reaches the position above the support table 21, the controller 76 detects the center of the edge ring 22 on the basis of information from the sensors 73a and 73b, and sends an instruction to the drive part 75 to transfer the object substrate 100, so as to cause the center position of the object substrate 100 under transfer to agree with the center position of the edge ring 22 thus detected. Here, at this time, it is assumed that a deviation of the center position of the object substrate 100 relative to the reference position of the arm 71 is calculated by the controller 76 by using the sensor 53 provided at the opening 15 and the position of the arm 71 passing through the opening 15.

Further, the controller 76 may control the operations of the plasma processing apparatus 10 as a whole. For example, the controller 76 conducts transfer of the object substrate 100 into and out of the chamber 11, opening and closing of the shutter 52, pressure reduction inside the chamber 11, a plasma process, and so forth, in accordance with a predetermined recipe. In this embodiment, an explanation will be given of transfer position control for the object substrate 100 in detail, hereinafter.

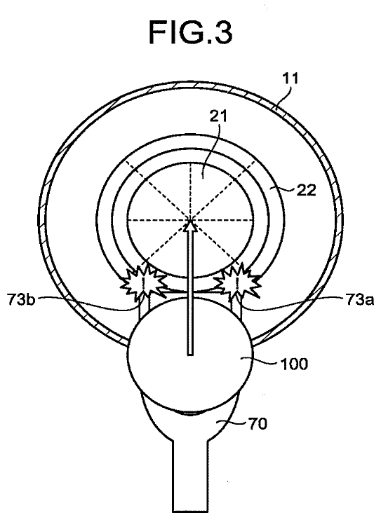

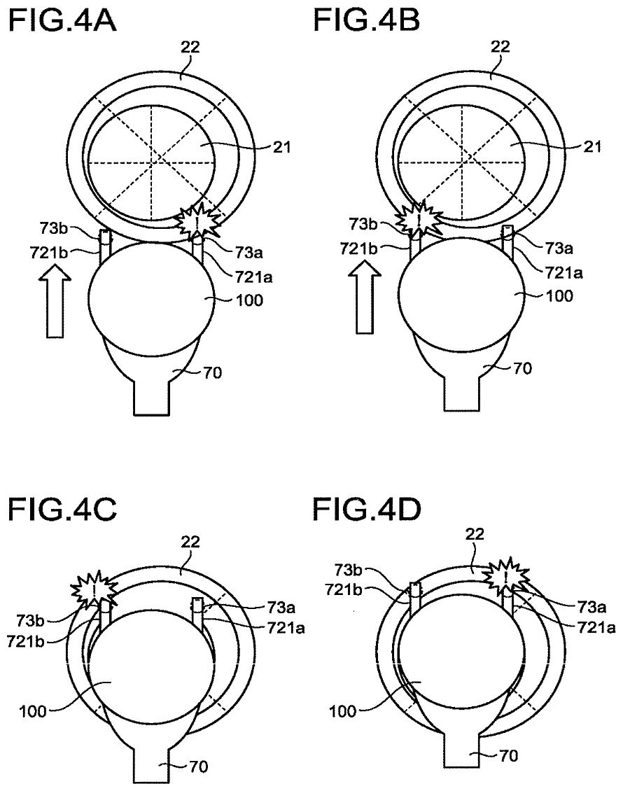

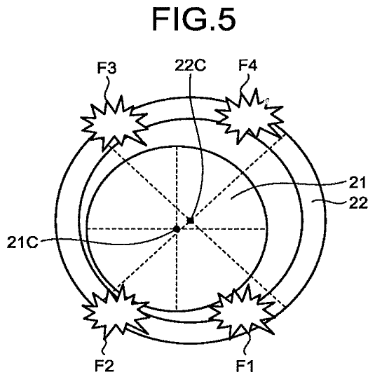

FIG. 3 is a diagram illustrating an example of a transfer method for an object substrate in an ideal state. FIGS. 4A to 4D are diagrams illustrating an example of detection of the position of the edge ring according to the first embodiment. FIG. 5 is a diagram illustrating an outline of a placement position correcting method for an object substrate according to the first embodiment. In a state where an object substrate 100 is placed on the pick 72, the transfer arm 70 is driven to position the object substrate 100 above the support table 21. The transfer arm 70 is driven to cause the center position of the object substrate 100 to overlap with the center position of the support table 21. Here, the center position of the object substrate 100 on the transfer arm 70 has been calculated by using the sensor 53 when the object substrate 100 passes through the opening 15 of the chamber 11.

As illustrated in FIG. 3, when the center of the edge ring 22 agrees with the center of the support table 21, the sensors 73a and 73b provided on the two substrate holding members 721 of the transfer arm 70 detect the edge ring 22 simultaneously with each other, as the transfer arm 70 transfers the object substrate 100. In this way, when the center of the edge ring 22 agrees with the center of the support table 21, the sensors 73a and 73b come to detect the edge ring 22 simultaneously with each other.

On the other hand, when the center of the edge ring 22 does not agree with the center of the support table 21, the sensors 73a and 73b come to detect the edge ring 22 at timings deviating from each other. For example, as illustrated in FIGS. 4A to 40 where the lower side in each of these drawings is the front side, it is assumed that the center of the edge ring 22 deviates from the center of the support table 21 to the right rear side. In this case, as the transfer arm 70 is moved, as illustrated in FIG. 4A, the sensor 73a provided on the substrate holding member 721a on the right side detects the edge ring 22, first. Then, after a while, as illustrated in FIG. 4B, the sensor 73b provided on the substrate holding member 721b on the left side detects the edge ring 22. As the transfer arm 70 is further moved, as illustrated in FIG. 4C, the sensor 73b provided on the substrate holding member 721b on the left side detects the edge ring 22. Then, after a while, as illustrated in FIG. 40, the sensor 73a provided on the substrate holding member 721a on the right side detects the edge ring 22. The detection results thus obtained by the sensors 73a and 73b are transmitted to the controller 76, and the edge ring 22 is thereby detected.

As illustrated in FIG. 5, the controller 76 calculates a circle passing though four points F1 to F4 on the edge ring 22 detected by the two sensors 73a and 73b of the transfer arm 70, and calculates the center position of this circle as the center position 220 of the edge ring 22. Then, the controller 76 calculates an offset including its direction, about the center position 220 of the edge ring 22 relative to the center position 210 of the support table 21. Then, the controller 76 outputs an instruction for position correction to the drive part 75 for the transfer arm 70, on the basis of the offset thus calculated, to cause the center position of the object substrate 100 under transfer by the transfer arm 70 to agree with the center position 220 of the edge ring 22.

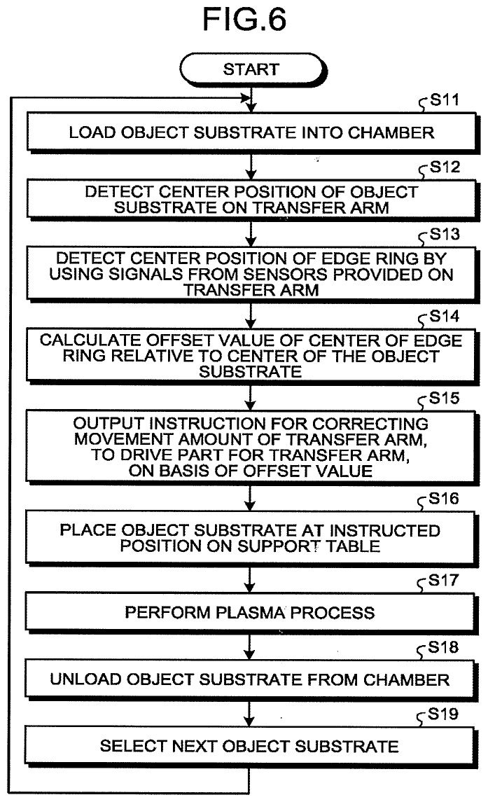

Next, an explanation will be given of a plasma processing method and a semiconductor device manufacturing method in the plasma processing apparatus described above. FIG. 6 is a flowchart illustrating an example of the sequence of a plasma processing method according to the first embodiment. First, under the control of the controller 76, an object substrate 100 for use in semiconductor device manufacturing is loaded into the chamber 11 (step S11). For example, the object substrate 100 is placed on the pick 72 of the transfer arm 70, and is transferred into the chamber 11 through the opening 15 with the shutter 52 opened.

Further, a signal from the sensor 53, obtained when the object substrate 100 passes through the opening 15, used to detect the center position of the object substrate 100 relative to the reference position of the transfer arm 70 (step S12).

Then, the controller 76 uses signals from the sensors 73a and 73b provided on the transfer arm 70 to detect the center position of the edge ring 22 (step S13). Here, as described with reference to FIGS. 4A to 4D, the controller 76 acquires the detection positions of four points on the edge ring 22 from detection results obtained by the sensors 73a and 73b. Further, the controller 76 calculates a circle passing through the detection positions of four points on the edge ring 22, and calculates the center position of this circle as the center position of the edge ring 22. At this time, the transfer arm 70 is stopped at the position by which the center position of the object substrate 100 overlaps with the center position of the support table 21.

Thereafter, the controller 76 calculates an offset value of the center position of the edge ring relative to the center position of the object substrate 100 (support table 21) (step S14). Specifically, the controller 76 calculates in which direction and how much distance the center position of the edge ring 22 deviates from the center position of the object substrate 100 (support table 21).

Thereafter, on the basis of the offset value, the controller 76 outputs an instruction for correcting the movement amount of the transfer arm 70, to the drive part 75 for the transfer arm 70 (step S15). The transfer arm 70 is driven in accordance with the instruction from the controller 76, to place the object substrate 100 at the instructed position on the support table 21 (step S16). Consequently, the center position of the object substrate 100 agrees with the center position of the edge ring 22.

Then, under the control of the controller 76, a plasma process is performed (step S17). For example, the pressure inside the chamber 11 is reduced, and, when the pressure reaches a predetermined vacuum level, a gas for use in the plasma process is supplied into the chamber 11. Further, a voltage is applied between the support table 21 and the upper electrode 42 to generate plasma, and the plasma process (here, an etching process) is performed to the object substrate 100 on the support table 21. Thereafter, under the control of the controller 76, the object substrate 100 is unloaded from the chamber 11 (step S18). Then, a next object substrate 100 is selected (step S19), and the processing sequence returns to step S11.

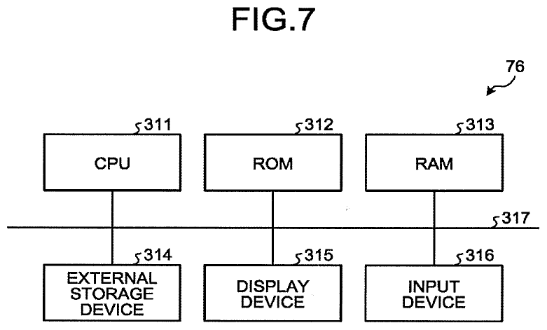

FIG. 7 is a diagram illustrating a hardware configuration example of the controller. The controller 76 has a hardware configuration utilizing an ordinary computer, in which a Central Processing Unit (CPU) 311, a Read Only Memory (ROM) 312, a Random Access Memory (RAM) 313 serving as the main storage device, an external storage device 314, such as a Hard Disk Drive (HOD), Solid State Drive (SSD), or Compact Disc (CD) drive device, a display device 315, su h as a display device, and an input device 316, such as a keyboard and/or a mouse, are included, and are connected to each other via a bus line 317.

A program to be executed by the controller 76 according to the embodiment has been prepared to perform the method illustrated in FIG. 6. This program is provided in a state recorded in a computer-readable recording medium, such as a CD-ROM, flexible disk (FD), CD-R, or Digital Versatile Disk (DVD), by a file in an installable format or executable format.

Alternatively, a program to be executed by the controller 76 according to the embodiment may be provided such that the program is stored in a computer connected to a network, such as the internet, and is downloaded via the network. Further, a program to be executed by the controller 76 according to the embodiment may be provided such that the program is provided or distributed via a network, such as the internet.

Alternatively, a program according to the embodiment may be provided in a state incorporated in a ROM or the like in advance.

In the first embodiment, the sensors 73a and 73b are provided at line symmetric positions on the face (rear face) opposite to the substrate placing face of the pick 72. An object substrate 100 is transferred to cause the center of the object substrate 100 to agree with the center of the support table 21, and the sensors 73a and 73b detect the edge ring 22 during this transfer. On the basis of the detection results obtained by the sensors 73a and 73b at this time, the center position of the edge ring 22 is detected. Then, an offset value of the center position of the edge ring 22 relative to the center position of the object substrate 100 is calculated. On the basis of this offset value, the movement amount of the transfer arm 70 is corrected, and the object substrate 100 is transferred by the transfer arm 70 to cause the center position of the object substrate 100 to overlap with the center position of the edge ring 22. Consequently, an effect is obtained such that, even if the center position of the edge ring 22 has been arranged with a deviation from the center position of the support table 21, it is possible to reduce the processing rate asymmetry at the outermost periphery of the object substrate 100 generated by the positional deviation of the edge ring 22 relative to the support table 21.

### Second Embodiment

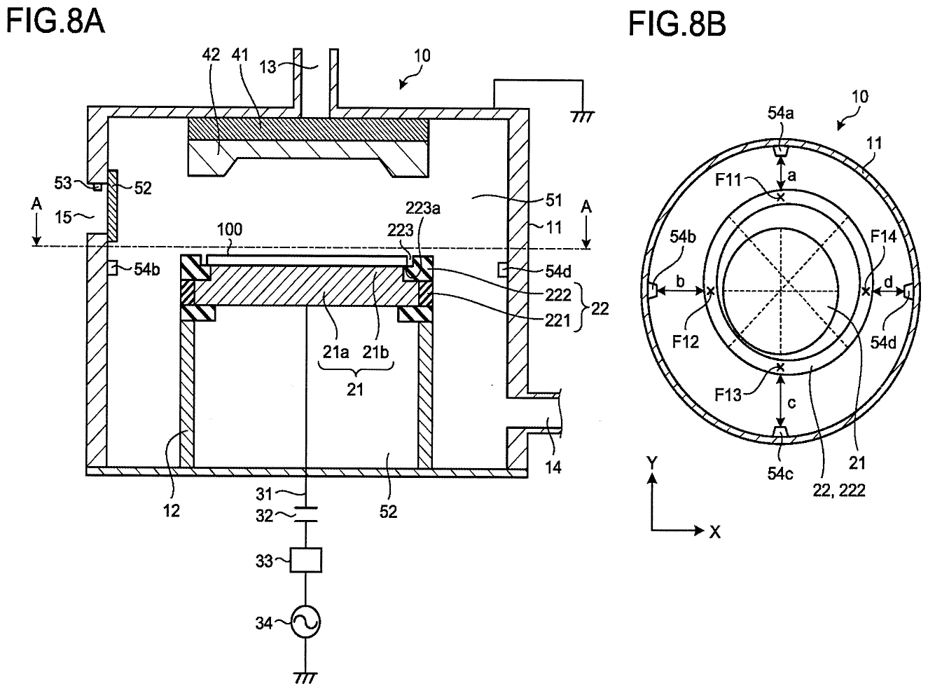

FIGS. 8A and 8B are diagrams schematically illustrating a configuration example of a plasma processing apparatus according to a second embodiment. Here, FIG. 8A is a sectional view, and FIG. 8B is a sectional view taken along a line A-A of FIG. 8A. In the second embodiment, a circular cylindrical chamber 11 is equipped with sensors 54a to 54d at predetermined positions on the inner surface of the chamber 11, and each of the sensors is configured to measure the distance of the edge ring 22 from the inner surface. For example, the sensors 54a to 54d are arranged at points where two directions (assumed to be an X-axis direction and an Y-axis direction), which pass through the center of the substrate mounting surface of the support table 21 and are perpendicular to each other in a plane parallel with the substrate mounting surface, intersect with the inner wall of the chamber 11. The sensors 54a to 54d are arranged within the height range of the arrangement position of the upper edge ring 222. In this respect, although the first embodiment includes the sensors 73a and 73b provided on the pick 72 of the transfer arm 70, the second embodiment excludes the sensors 73a and 73b provided on the pick 72 of the transfer arm 70.

In accordance with distance information output from the sensors 54a to 54d, the controller 76 calculates an offset amount (deviation) of the center of the edge ring relative to the center of the support table 21. Specifically, the controller 76 calculates a circle passing though four points F11 to F14 that have distances “a”, “b”, “c”, and “d” from the inner wall of the chamber 11, measured respectively by the sensors 54a to 54d, and calculates the center position of this circle as the center position of the edge ring 22. Then, in accordance with the deviation of the center position of the edge ring 22 relative to the center position of the support table 21, the controller 76 performs feedback control to cause the center position of the object substrate 100 under transfer by the transfer arm 70 to agree with the center position of the edge ring 22.

Although the example of FIGS. 8A and 8B illustrates a case where the chamber 11 has a circular cylindrical shape, the chamber 11 may have a rectangular cylindrical shape. Here, the constituent elements corresponding to those described in the first embodiment are denoted by the came reference symbols, and their description will be omitted. Further, as a plasma processing method in the plasma processing apparatus 10 according to the second embodiment is substantially the same as that described with reference to FIG. 6 according to the first embodiment, its description will be omitted.

Also in the second embodiment, an effect substantially the same as that of the first embodiment can be obtained.

Here, in the above description, the plasma processing apparatus 10 is illustrated with a structure in which the upper edge ring 222 is directly mounted on the lower edge ring 221; however, the embodiments are not limited to this structure. For example, the upper surface of the lower edge ring 221 may be provided with pins movable up and down to place the upper edge ring 222 on the pins. In a case where the edge ring 22 has this structure, when the upper surface of the upper edge ring 222 is consumed, for example, the position of the upper surface of the upper edge ring 222 can be adjusted by changing the height of the pins. In this structure in which the upper edge ring is supported by the pins, the center position of the upper edge ring 222 relative to the center position of the support table 21 changes with time due to vibration or the like of the plasma processing apparatus 10. Even in such a case, the plasma processing apparatus 10 according to each of the embodiments can cause the center position of an object substrate 100 to agree with the center position of the edge ring 22. As a result, an effect is obtained to reduce the processing rate asymmetry at the outermost periphery of the object substrate 100.

Further, in the above description, the plasma processing apparatus 10 is exemplified by an RIE apparatus; however, the structure of the plasma processing apparatus 10 may be applied to a plasma Chemical Vapor Deposition (CVD) apparatus, sputtering apparatus, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma processing apparatus comprising:
a support table configured to support a substrate in a chamber;
an edge ring provided at an outer periphery of the support table on a side with a mounting surface for placing the substrate thereon;
a transfer arm configured to transfer the substrate onto the support table,
a sensor configured to detect a position of the edge ring;
a drive part configured to drive the transfer arm; and
a controller configured to control the drive part, wherein
the controller is configured to
calculate an offset amount between a center position of the edge ring and a center position of the substrate under transfer by the transfer arm, on a basis of information output from the sensor, and
correct a movement amount of the transfer arm by using the offset amount.

2. The plasma processing apparatus according to claim 1, wherein the sensor includes a plurality of sensors provided on a face of the transfer arm opposite to a face for placing the substrate thereon.

3. The plasma processing apparatus according to claim 2, wherein
the mounting surface of the support table has a circular shape, and
the edge ring has a circular ring shape.

4. The plasma processing apparatus according to claim 2, wherein
the transfer arm includes a pick holding the substrate, and an arm having one end supporting the pick and another end connected to the drive part, and
the sensors are provided on a face of the pick opposite to a face placing the substrate thereon.

5. The plasma processing apparatus according to claim 4, wherein the sensors are provided at line symmetric positions with respect to an extension line formed by extending the arm toward the pick.

6. The plasma processing apparatus according to claim 5, wherein the pick is U-shaped.

7. The plasma processing apparatus according to claim 1, wherein the sensor includes a plurality of distance sensors provided on an inner wall of the chamber, and the distance sensors are configured to measure a distance between the inner wall and a side surface of the edge ring.

8. The plasma processing apparatus according to claim 7, wherein the distance sensors are arranged at points where two directions, which pass through a center of the mounting surface of the support table and are perpendicular to each other in a plane parallel with the mounting surface, intersect with the inner wall of the chamber.

9. The plasma processing apparatus according to claim 1, wherein
the edge ring includes a lower edge ring secured on a side surface of the support table on a lower side, and an upper edge ring arranged above the lower edge ring, and
the sensor is configured to detect a position of the upper edge ring.

10. The plasma processing apparatus according to claim 9, wherein
an upper surface of the lower edge ring is provided with pins movable up and down, and
the upper edge ring is supported by the pins.

11. A semiconductor device manufacturing method comprising:
loading a substrate into a chamber by a transfer arm;
detecting a position of an edge ring provided at an outer periphery of a support table configured to support the substrate in the chamber;
detecting a position of the substrate on the transfer arm;
calculating an offset value between a center position of the edge ring and a center position of the substrate under transfer;
correcting a movement amount of the transfer arm by using the offset value;
placing the substrate a position on the support table in accordance with correction thus given; and
performing a plasma process to the substrate in the chamber.

12. The semiconductor device manufacturing method according to claim 11, wherein, in the detecting the position of the edge ring, the position of the edge ring is detected on a basis of information from a plurality of sensors provided on a face of the transfer arm opposite to a face for placing the substrate thereon.

13. The semiconductor device manufacturing method according to claim 12, wherein
a mounting surface of the support table placing the substrate thereon has a circular shape, and
the edge ring has a circular ring shape.

14. The semiconductor device manufacturing method according to claim 12, wherein
the transfer arm includes a pick holding the substrate, and an arm having one end supporting the pick and another end connected to the drive part, and
the sensors are provided on a face of the pick opposite to a face for placing the substrate thereon.

15. The semiconductor device manufacturing method according to claim 14, wherein the sensors are provided at line symmetric positions with respect to an extension line formed by extending the arm toward the pick.

16. The semiconductor device manufacturing method according to claim 15, wherein the pick is U-shaped.

17. The semiconductor device manufacturing method according to claim 11, wherein, in the detecting the position of the edge ring, the position of the edge ring is detected on a basis of information from a plurality of distance sensors provided on an inner wall of the chamber, and the distance sensors are configured to measure a distance between the inner wall and a side surface of the edge ring.

18. The semiconductor device manufacturing method according to claim 17, wherein the distance sensors are arranged at points where two directions, which pass through a center of the mounting surface of the support table and are perpendicular to each other in a plane parallel with the mounting surface, intersect with the inner wall of the chamber.

19. The semiconductor device manufacturing method according to claim 11, wherein
the edge ring includes a lower edge ring secured on a side surface of the support table on a lower side, and an upper edge ring arranged above the lower edge ring, and
in the detecting the position of the edge ring, a position of the upper edge ring is detected.

20. The semiconductor device manufacturing method according to claim 19, wherein
an upper surface of the lower edge ring is provided with pins movable up and down, and
the upper edge ring is supported by the pins.
